(19) United States
(12) Patent Application Publication
(10) Pub. No.: US 2026/0093875 A1
(43) Pub. Date: Apr. 2, 2026

(54) MULTI-MODAL ADVERSARIAL OPTIMIZATION ENGINE AND DEPLOYMENT INTEGRATOR

(71) Applicant: The Adversarial Company, Inc., North Hollywood, CA (US)

(72) Inventor: Patrick Brian Bentley, JR., Los Angeles, CA (US)

(21) Appl. No.: 19/342,430

(22) Filed: Sep. 26, 2025

Related U.S. Application Data
(60) Provisional application No. 63/699,808, filed on Sep. 27, 2024.
(60) Provisional application No. 63/821,871, filed on Jun. 11, 2025.

(51) Int. Cl. G06F 30/27; G06V 10/776

(52) U.S. Cl. CPC G06F 30/27; G06V 10/776

(57) ABSTRACT

Disclosed is a system to influence detectability of a target object by machine perception. The system receives input data that includes a representation of the target object and an objective corresponding to reduce detectability or induce a designated detection of that object. The system generates a plurality of candidate adversarial patterns based on the objective for the object. For each candidate adversarial pattern, the system simulates an integration of the target object in a virtual environment across a plurality of sensor modalities. The system evaluates each simulated pattern against a plurality of sensor modalities and calculates a performance metric for each candidate. The system determines whether the metric reaches a predetermined threshold level for the objective. If not, it iteratively adjusts the candidate to converge on an optimized output adversarial pattern. If so, it confirms the pattern as optimized and compiles it for output.

### CROSS REFERENCE TO RELATED APPLICATIONS

This application claims the benefit of, and priority to, U.S. Provisional Application No. 63/699,808, filed Sep. 27, 2024, and U.S. Provisional Ser. No. 63/821,871, filed Jun. 11, 2025, the contents of each of which is incorporated by reference in its entirety.

### TECHNICAL FIELD

The disclosure relates generally to adversarial pattern generation and deployment systems for machine perception, and more particularly, an adaptive multi-modal system configuration to generate adversarial signals and patterns across physical, electronic, and digital domains.

### BACKGROUND

Advances in computer vision, remote sensing, and artificial intelligence have made it increasingly feasible to automatically detect and recognize objects using machine learning models. Modern surveillance systems, autonomous vehicles, and military targeting platforms often employ deep neural network detectors to identify people, vehicles, weapons, and other assets from visual imagery, thermal infrared feeds, LiDAR point clouds, radar scans, and other sensor data. However, alongside the proliferation of AI-based detection systems, it has become evident that these models are vulnerable to adversarial examples-inputs deliberately perturbed to mislead the model's predictions. Researchers have demonstrated both digital adversarial attacks (where small pixel perturbations in an image cause misclassification) and physical adversarial attacks (where objects adorned with specially crafted patterns, sometimes called adversarial patches, cause detectors to fail to detect the object or to misidentify it). These findings underscore a new opportunity and threat, which is the same AI that enables advanced sensing may be deceived under the right conditions.

Existing attempts at physical adversarial camouflage have shown the potential to fool AI vision systems, but they suffer from critical limitations. Many patterns effective against machine-learning detectors appear as unnatural, high-contrast graphics or random noise that, while confusing to a computer vision model, are easily noticed by a human observer. For example, a shirt or vehicle wrap with a random-looking, high-frequency adversarial pattern might cause an AI-based camera to overlook a person entirely, but that same pattern appears conspicuous and bizarre to human eyes. This defeats the purpose of camouflage in practical scenarios because an effective modern solution must fool machines without alerting human observers. Traditional camouflages used by militaries or in nature rely on naturalistic textures and colors to blend into the environment, but such conventional camouflage is not designed to defeat AI-based detectors. There is thus a gap between patterns that fool machines and those that fool humans. A truly modern stealth technique must address both aspects simultaneously.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIG. 1A illustrates and example stealth adversarial artificial intelligence (AI) system according to one embodiment.

FIG. 1B illustrates a block diagram of an example adversarial optimization and deployment system architecture in accordance with one embodiment.

FIG. 2 illustrates a process for generating an example adversarial pattern in accordance with one embodiment.

FIG. 3 illustrates a process for deploying an example optimized adversarial pattern onto a target in accordance with one embodiment.

FIG. 4 illustrates an operational flow of an example deployment scenario with multiple distributed devices receiving adversarial patterns from a server system in accordance with one embodiment.

FIG. 5 illustrates an example machine to read and execute computer readable instructions in accordance with an embodiment.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Introductory Overview

In the disclosed configuration “stealth mode” or “camouflage mode” may be used to refer to the adversarial camouflage functionality, for example, concealing physical objects (e.g., real world objects). Also in the disclosed configuration, “decoy mode” may refer to the adversarial decoy functionality, for example, creating or generating false target physical objects. For convenience, the intended objective of a given adversarial pattern, i.e., stealth or decoy, may be referred to as a pattern intent.

Further, the disclosed configuration provides a system (e.g., an apparatus and method) for adversarial pattern generation and deployment systems for machine perception. Machine perception may be, for example, a computing device with artificial intelligence (AI) and machine learning (ML) that is configured to review data of an environment to detect presence of an object in that environment. The detection may be, for example, visual, thermal, acoustic, or radar. Machine perception may be used with human input in which the human also may augment an analysis by the machine. Modulating machine perception in an adversarial computing system may include, for example, how an AI/ML architecture perceives an environment that it is analyzing and also may include hiding or deceiving what a human or machine observer may observe or not observe in an environment.

The disclosed configuration includes an adaptive multi-modal system and method for generating adversarial patterns. The adversarial patterns that are generated may be output as physical patterns or electronic signal patterns. The generated adversarial patterns may be applied across physical, electronic, and digital domains. Integrating the adversarial patterns across such domains in real-world deployments on various target objects (e.g., devices and media) enables concealing (or cloaking (e.g., camouflage or signal noise)) of such objects when a stealth mode is desired or identification of an object in decoy mode that is not intended to be an object of interest. Hence, the generation and deployment of adversarial patterns influences adversarial perception systems processing of data sensed, e.g., visual or emitted data. This enables counter-detection measures against adversarial perception machines (and systems) to conceal real assets (stealth application), induce (or create) decoy patterns (e.g., visual or emitted) to produce false targets (deception (or decoy) application), and enhancing the visibility of selected objects to machine sensors (visibility maximization), across a variety of sensor modalities.

In some embodiments, the adversarial pattern generation system described herein may be implemented as part of a broader core platform that integrates multiple modules, which may be an overall integrator” platform for adaptive adversarial countermeasures The system architecture and modules described below correspond to components of such a platform. For example, modules for pattern generation, multi-modal simulation, detector ensembles, and optimization may be shared with the core integrator framework. The present description focuses on the novel aspects of generating adversarial camouflage and decoy patterns across visual and non-visual modalities using that architecture. Modules or functionality that are common with the core platform are referenced for context.

A multi-modal adversarial optimization system and deployment integrator are disclosed for modulating the detectability of physical or digital objects to machine perception systems. The system comprises an adversarial pattern generation engine that receives target object data and context parameters and produces candidate camouflage or decoy patterns optimized to either reduce the object's detectability (stealth) or induce false-positive detections of nonexistent objects (decoy), as well as to optionally maximize detectability for friendly identification. The engine incorporates a multi-modal simulation environment and an ensemble of detector models representing various sensor modalities (e.g., visual, infrared, LiDAR, radar) to evaluate each pattern candidate performance. An optimization loop iteratively refines the pattern using AI techniques (such as evolutionary algorithms, neural networks, or gradient-based methods) based on feedback from the detector ensemble until an optimized adversarial pattern meeting a desired objective is obtained. The system further includes a deployment integrator that compiles the optimized pattern into device-specific output instructions or files (for example, print layouts, display configurations, or emitter control signals) and interfaces with output devices to apply or project the pattern onto the target object or environment. The integrator module handles tasks such as pattern tiling, geometric distortion correction for curved surfaces, color calibration, insertion of alignment marks, and ensures compliance with device and safety constraints. A verification subsystem captures sensor data of the object after deployment and analyzes it (using the same detector models) to verify that the deployed pattern achieves the intended adversarial effect; if deviations are detected, automatic adjustments or re-deployment can be performed. The system supports real-time operation on edge devices and can distribute pattern updates across a networked fleet of objects, allowing continuous adaptation to evolving conditions or adversary countermeasures. This integrated method and system enable robust, adaptive adversarial camouflage and decoy deployments across multiple sensor modalities, bridging the gap between algorithmic pattern generation and real-world implementation.

Conventional adversarial camouflage methods are static and narrowly optimized. A pattern that is printed or painted onto an object may lose effectiveness if viewing conditions change (e.g. different angles, distances, or lighting) or if the adversary updates or retrains their detection algorithms. Some research efforts have introduced environment-blended adversarial textures (for instance, styling perturbations to look like art or natural camouflage) and three-dimensional (3D) adversarial wraps that cover a full surface of an object for multi-angle protection. Unlike conventional approaches, the disclosed configuration allows for multi-modal detection scenarios where an object could be simultaneously observed by different types of sensors. The disclosed configuration beneficially allows an asset that visually blends into the background to protect against being revealed by other signatures, for example, an infrared camera can spot the object's thermal emissions at night, a LiDAR scanner can detect its shape via active depth sensing, or a radar system can bounce signals off it to detect its presence. Further, the disclosed configuration intelligently optimizes across multiple sensor modalities or adapts its strategy against the AI itself. For example, an intelligent camouflage approach as disclosed herein generates natural-looking, robust adversarial patterns against a range of detectors and that can evolve over time as conditions or adversary capabilities change.

Beyond concealment of true objects, deception has long been a strategy in warfare and security, for example, using decoys to mislead an adversary. Historical examples range from inflatable dummy tanks and aircraft to simple radar reflectors or heat sources intended to create phantom signals on sensors. Traditional decoys, however, are often crude and limited to mimicking one aspect of a target (e.g. just a visual likeness or a single radar blip) and may be easily identified as fake or impractical to deploy at scale. The disclosed configuration includes an AI-driven multi-sensor surveillance that provides for an adversarial decoy system that generates convincing false targets for machine perception. In essence, the disclosed configuration generates patterns, signals, or combinations thereof that cause an AI-based object detector to confidently report an object that otherwise is not present where a system may identify as being there. For example, an intelligent decoy might be a strategically placed arrangement that an AI vision model interprets as a human or vehicle (when none exists), or an electronic emitter broadcasting a spoofed thermal or radar signature of a target. These AI-optimized decoys could overload an adversary's tracking systems with numerous bogus detections or divert attention away from real assets, thereby confounding targeting and surveillance efforts. However, much like camouflage, prior decoy techniques have been siloed and simplistic, often focusing on a single sensor domain or using predetermined templates.

The disclosed configuration combines adversarial camouflage (hiding the real) and adversarial decoys (simulating the fake) in a single adaptive framework operable across diverse sensors. The disclosed adversarial targeting system provides a generalized, inverse optimization of detectability. For example, a system algorithmically minimizes visibility of an object or, conversely, maximize it (even creating fictitious targets), as required. The disclosed configuration is structured to produce robust, multispectral camouflage to conceal real objects and also generate deceptive patterns/signals to create illusory objects, in order to defeat or misdirect AI-based detection systems. In some cases, it may even be desirable to increase a machine detectability of a friendly object for positive identification or safety, for example, outfitting a rescue vehicle or a pedestrian with a pattern that AI vision systems recognize with high confidence (a visibility enhancement application).

The disclosed configuration also transitions optimized patterns from the digital realm into physical or deployed form. The disclosed configurations accounts for constraints and transformations of a pattern to be transferred onto an object. The raw outputs of pattern-generation algorithms account for a physical object type and what is to be applied, for example, a printed vinyl wrap, a painted surface, an electronic display, or an RF/IR emission device. The disclosed configuration protects transformations against degradation or destruction of adversarial properties of the pattern. For example, the disclosed configuration may account for printing processes that may have limited resolution and color gamut, displays that may have fixed pixel grids and brightness limits, optical projections onto curved surfaces that may introduce distortion, and radio-frequency or thermal emitters that may have discrete output levels and regulatory constraints.

The disclosed configuration is an end-to-end system that not only generates optimized adversarial camouflage/decoy patterns as described above, but also deploys those patterns effectively in the field. It provides a unified multi-modal adversarial optimization engine and deployment integrator that is an integrated framework that algorithmically produces adversarial patterns or signals to modulate detectability and ensures their faithful implementation and verification across diverse sensors, devices, and real-world conditions.

### Configuration Overview

The disclosed configuration provides a system (e.g., an apparatus and method) for a unified adaptive adversarial optimization system for modulating the detectability of objects to artificial intelligence (AI) (including machine learning (ML)) and other machine perception systems. By way of example, the system generates and deploys adversarial patterns or other sensor stimuli that either reduce detectability of an asset (e.g., a physical object or rendered image on a screen). The system renders a real object effectively “invisible” or unrecognizable to AI detectors or produce a decoy signature that increases detectability in a controlled manner that causes a non-existent or irrelevant object to be falsely detected. Unlike traditional static camouflage or pre-designed decoys, this system employs advanced AI-driven techniques to create context-aware, machine-optimized patterns that fool or manipulate detection models while remaining plausible and inconspicuous in the real world. In essence, the same core engine can protect real physical (or digital) assets from being detected by machine learning algorithms and can also project false targets or enhanced markers that mislead or aid those algorithms, all without alerting human observers via any obvious anomalies.

The disclosed configuration may be embodied in various forms, including but not limited to a computer-implemented process for adversarial pattern/signal generation and deployment for stealth, deception, or visibility enhancement, a system or apparatus that implements the processes disclosed (including software modules and hardware components for generation, evaluation, deployment, and verification of adversarial patterns), (3) a non-transitory computer-readable medium containing program instructions for carrying out the processes disclosed; and the adversarial artifacts or manufactured products created or used by the system, such as the physical patterned materials, devices, or prepared signals that achieve the stealth or decoy effect. The scope of the disclosure spans the process, the enabling equipment/logic, and the resulting specialized articles (e.g. a printed camouflage wrap or an encoded decoy signal package).

In one embodiment, a system provides for an adversarial camouflage or decoy pattern to modulate the detectability of a target object. The system involves receives input data describing the target object and context, and using a generative model or other algorithm (for example, a generative adversarial network (GAN), variational autoencoder, diffusion model, evolutionary algorithm, or reinforcement learning agent) to synthesize an initial set of candidate patterns. These candidate patterns may be constrained or guided by input parameters. Input parameters may include, for example, a user specified desired camouflage style or provide data about the operational environment so that the generated pattern incorporates colors, textures, and features drawn from that environment. Each candidate pattern may be virtually applied to a model of the target object (e.g. a three-dimensional (3D) digital model or a set of images of the object) and evaluated for detectability using a suite of object detection algorithms. Essentially, an ensemble of AI detectors, which may cover various model architectures and sensor types, may be used to simulate how an adversary perception system would perceive the object with that pattern. A performance metric, for example a detection confidence score or classification result from each model, is computed for each pattern to indicate how successfully the generated pattern avoids or induces detection by the ensemble. The system may iteratively adjust the candidate patterns based on these metrics, for example, using optimization techniques such as evolutionary selection, gradient-based refinement, or policy learning until an optimized adversarial pattern is obtained that meets the desired stealth or decoy objective. An finalized optimized pattern design, along with any associated deployment metadata, may be output, for example, as one or more image files, print layouts, or device control instructions for implementation.

In another embodiment, a system deploys an adversarial pattern through a process that may begin with receiving a high-level pattern specification (or “pattern intent file”) from an upstream optimization engine. The system selects or receives a target output device or medium for deployment. The system transforms the pattern specification into one or more device-specific output files or signals. This may include operations such as print tiling, display mapping, emitter signal packaging, file formatting, and insertion of alignment marks. The system drives one or more target output devices to produce or apply the pattern in the physical world. The system captures sensor feedback, for example, via cameras, thermal imagers, LiDAR scanners, or other sensors, to verify the deployed pattern's accuracy and effectiveness. The system may further analyze the captured data to generate a verification report and automatically initiate corrections or re-compilation of the pattern deployment if the verification indicates any significant deviation from the intended pattern. In this way, the deployment process may be a closed-loop in which the system may issue the pattern to a device and also provide for checks to help ensure that the real-world result matches the designed adversarial effect, correcting for any errors in execution.

In yet another embodiment, a system may be configured for adversarial pattern generation and deployment. The system may include the following components that are communicatively coupled for processing. An input interface or module is configured to ingest target object data and context parameters, for example, environmental background characteristics, threat sensor profiles, and user-defined objectives. The system may include a pattern generation engine that includes sub-modules for candidate pattern synthesis and an optimization core for refining those patterns. The system may include a multi-modal simulation module that evaluates the generated pattern candidates in a virtual environment. An ensemble of machine-learning detectors representing adversary or observer sensors is configured to score the generated patterns.

The system may further include an output compilation module is configured generating device-specific pattern formatting for a final generated pattern. A deployment integrator module is configured to control output hardware and perform post-deployment verification. For example, the system may include a print pipeline module that handles image tiling, color calibration, and registration mark generation for printers and robotic painters; a display mapping module for configuring pixelated displays, e.g., e-ink screens, LED panel arrays, or projectors. This output may include any geometry distortion correction and luminance adjustment. In addition, the system may include a signal packaging module that is configured to program non-visual emitters such as RF transponders or thermal element arrays.

The system further comprises one or more output interfaces to various hardware devices (such as print heads, paint spray systems, display controllers, or signal emitters) and a verification subsystem integrating sensor inputs to capture the outcome of the deployment. The verification subsystem automatically measures the output via appropriate sensors corresponding to the modality, e.g. optical cameras for visual patterns, RF receivers for radio-frequency patterns, infrared cameras for thermal patterns, etc. It also may compare the output against expected pattern parameters and output a verification report. This closed-loop feedback allows the system to either alert operators or autonomously adjust the deployment, for example, by recalibrating device settings or updating a portion of the pattern) to ensure the deployed pattern meets its specifications and adversarial objectives.

In another embodiment, disclosed is a configuration to facilitate a deployment process for a generated pattern output. For example, a deployment bundle may be a packaged collection of files and configuration data prepared by the Integrator for a given deployment. A deployment bundle may include, for example: a panel map or tiling schema that divides a large pattern into segments or panels mapped to specific physical sections or output devices; the actual drive files or instructions for each device. By way of example, this output may be print files in a printer's native format for each tile, robot control code for each painted section, image or video files for display panels or projectors, or waveform data for an RF emitter. It also may include calibration and registration information such as alignment marks or fiducial placements to ensure those segments align correctly when assembled. There also may be a verification plan or baseline sensor data used by the verification subsystem to compare against the deployed results. Another manufactured item encompassed by the invention is the verification report generated post-deployment -essentially a data product that documents the outcome of the deployment, including any discrepancies between intended and actual pattern output, which can be stored as proof of performance or as input for further pattern refinement. These artifacts (the deployment bundle and verification report) enable traceability and iterative improvement for each adversarial pattern deployment.

The disclosed configuration beneficially delivers a robust and versatile solution that covers the full lifecycle of adversarial pattern use from initial pattern generation through final deployment and feedback. By integrating the generation engine with the deployment integrator, the system ensures that AI-optimized stealth or decoy designs do not remain stuck in simulation but can be reliably manifested in practice. This end-to-end approach significantly reduces deployment time and errors, protects the integrity of adversarial effects against real-world variables, and enables scalable use of adversarial patterns across many platforms and domains. The various features and embodiments of this invention will be described in further detail below, with reference to exemplary figures and scenarios, followed by claims that define the scope of the proprietary rights sought.

### Stealth Adversarial AI System Overview

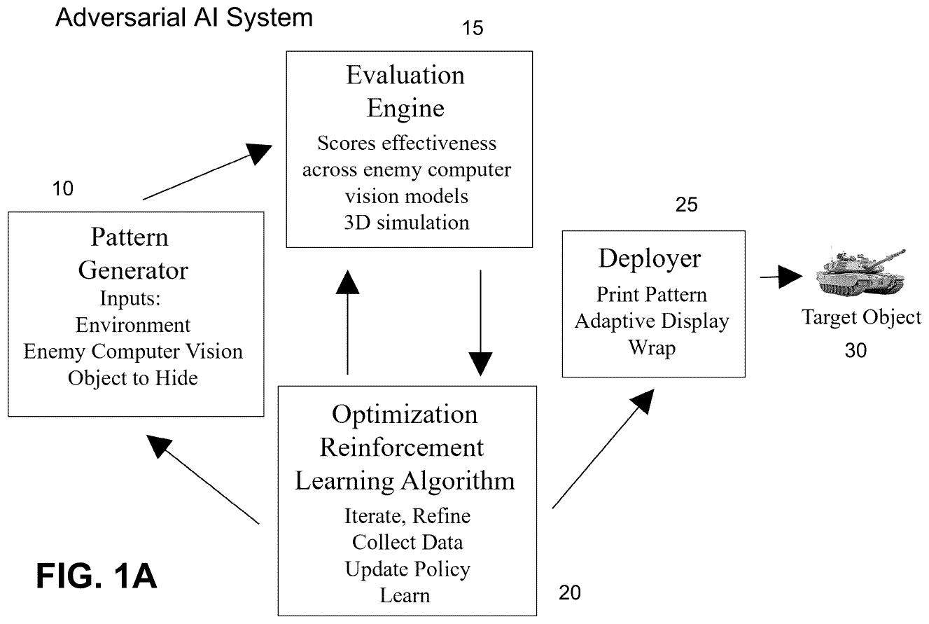

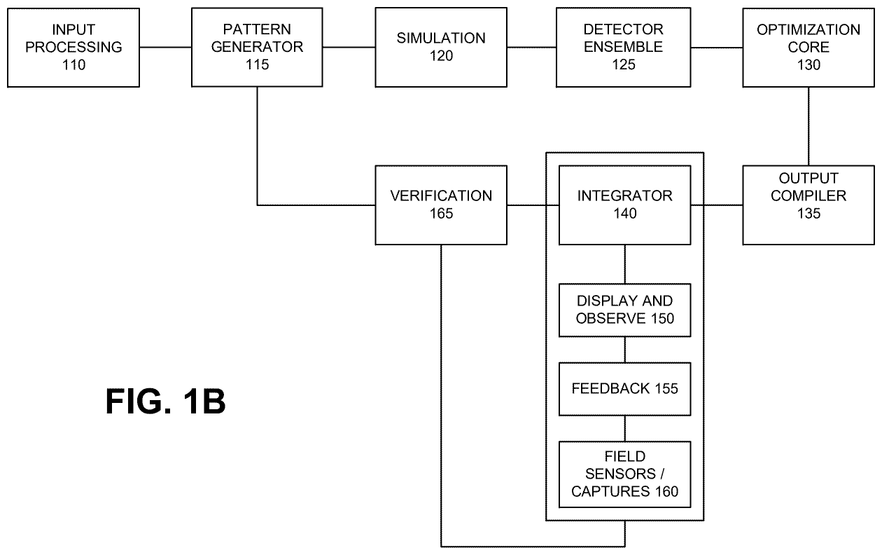

FIG. 1A illustrates and example adversarial artificial intelligence (AI) system according to one embodiment. By way of example, a system adaptively generates an adversarial pattern to reduce the detectability of a target object 30 or to generate a decoy to that represents an actual target object 30, though is not intended to be the actual target object. The target object 30 may be a physical object or a digital display (e.g., electronic display or screen).

The system includes a pattern generator 10, an evaluation engine 15, an optimization reinforcement learning algorithm 20, and a deployment module 25. The pattern generator 10 may include a generative model (e.g., a generative adversarial network, variational autoencoder, diffusion model, evolutionary algorithm, or other AI-based generator) to synthesize an initial set of candidate camouflage patterns. These candidate patterns may be constrained or guided by input parameters. For example, a user or operator may specify a desired camouflage style or provide data about the operational environment so that the generated pattern incorporates colors, textures, and features drawn from that environment so that adversarial AI detection systems are unable to detect the item. The pattern generator 10 may use one or more object detection algorithms to generate a pattern based on the inputs to generate a patterned image that will be applied to a physical object. The pattern image may be generated as an output for application on the target object 30. The output may be a physical print (e.g., vinyl sheets), a guidance document for how to apply a specified image, or an electronic image that may be uploaded onto a display medium on the physical object. In the case of a decoy, the output may be a representation of the target object 30 through not the actual target object.

The evaluation engine 15 is configured to evaluate detectability of an object by scoring the effectiveness of a generated patterns against simulations of an adversarial AI machine vision model (e.g., a three-dimensional simulation). For example, an ensemble of AI detectors (covering various model architectures and sensor types) may be used to simulate how an adversary's perception system would perceive the object with that pattern. A performance metric (such as detection confidence scores from each model) is computed for each pattern, indicating how successfully it avoids detection by the ensemble.

The optimization reinforcement learning engine 20 of the system iteratively refines the patterns. For example, an optimization reinforcement learning engine 20 modifies the candidates to improve their stealth performance, guided by an optimization technique such as an evolutionary algorithm (which evolves a population of patterns over successive generations via selection, crossover, and mutation) or reinforcement learning (which treats pattern generation as an agent being rewarded for evasion success). This information may be fed back to the pattern generator 20. This generate-evaluate-optimize loop repeats until an optimized camouflage pattern is obtained that minimizes the probability of the target object being detected by any of the ensemble models. Importantly, during this process the candidate patterns can also be checked against human-visibility criteria. Further, it may filter out any designs that look conspicuously artificial or otherwise draw unwanted attention from human observers.

The deployer module 25 generates a final adversarial camouflage pattern. The pattern may be a physical print (e.g., vinyl sheets or a wrap), a document describing how to apply a specified image, or an electronic image that may be uploaded onto a display medium on the physical object. The pattern is generated is meant to deceive machine detectors while remaining contextually natural to humans. Each candidate pattern is then virtually or physically applied to a model of the target object 30, e.g. a 3D digital model or a set of images of the object, for verification and/or deployment in a field setting for when the target object is in stealth configuration. When the target object 30 is in decoy configuration, the candidate pattern is generated to physically simulate the target object as though it is the actual object.

### Example Adversarial Optimization and Deployment System

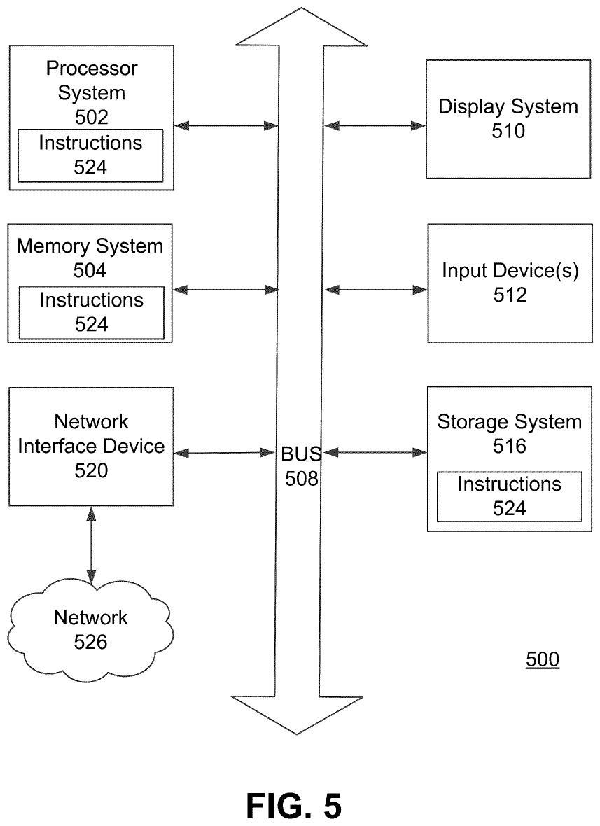

Embodiments disclosed include an integrated adversarial optimization and deployment system. The system may be implemented in software executing on computing hardware, in combination with various output devices and sensor devices. The computing hardware may include some or all of the components described with FIG. 5. By way of example, the system can be realized as a server or workstation connected to output hardware via network or direct interfaces, or as a distributed set of modules communicating over a network.

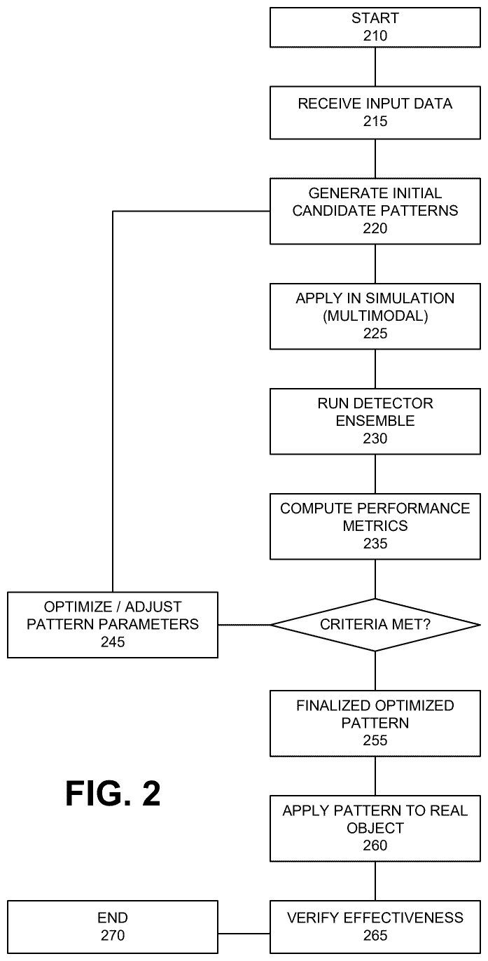

Referring now to FIG. 1B, illustrated is a schematic block diagram of an adversarial optimization and deployment system architecture in accordance with one embodiment. The system builds upon the components introduced with FIG. 1A. In FIG. 1B, adversarial optimization and deployment system architecture includes an input processing module 110, a pattern generator (or generation) module 115, a multi-modal simulation module 120, a detector ensemble evaluation module 125, an optimization core module 130, an output compiler (or compilation) module 135, an integrator (or integration) module 140, and a verification module 165. The input processing module 110 communicatively couples the pattern generator module 115. The pattern generation module 115 communicatively couples the multi-modal simulation module 120. The multimodal simulation module 120 communicatively couples the detector ensemble evaluation module 125. The detector ensemble evaluation module 125 communicatively couples the optimization core module 130. The optimization core module 130 communicatively couples the output compiler module 135. The output compiler module 135 communicatively couples the integrator module 140. The integrator module 140 communicatively couples the verification module 165. The verification module 165 may include a feedback loop 170 that communicatively couples the pattern generation module 115. The communications coupling may be through wired or wireless communication paths and/or may be segmented portions of program code that interact. These modules (or engines) work in concert to ensure that an adversarial pattern specified in digital form is faithfully and efficiently rendered in the desired physical or digital medium, and that it achieves the intended effect against machine perception systems. Each module of FIG. 1 is further described herein with the aid of FIG. 2. FIG. 2 illustrates a process for generating an example adversarial pattern in accordance with one embodiment.

### Input Processing and Context Specification

Referring initially to FIG. 2, at a start 210 of a process, e.g., in a stealth mode operation, the input processing module 110 receives 215 various input parameters defining the objectives and constraints for adversarial pattern generation. The input received may include a target object or class that corresponds to data identifying what real world (or physical) object is to be protected, for example, in a stealth mode or what target signature is to be mimicked or amplified in decoy or visibility-enhancement mode. This could be, for example, a digital model or images of a specific vehicle, person, or piece of equipment to be camouflaged; or conversely a specification like “tank” or “soldier” that a decoy should resemble. The system may ingest a detailed three-dimensional (3D) model of the target object or reference imagery, or simply a category label (e.g., “pickup truck”) if a generic target type is to be considered. For a visibility-maximization scenario, the target object might be something like a pedestrian figure or road obstacle that needs to be highlighted to machine vision.

The input processing module 110 also may receive input for an objective mode, which may include one or more parameters indicating the goal of the adversarial design. e.g., stealth to minimize detectability of the real target, decoy to create a false positive detection of a faux target, or max visibility to intentionally maximize detectability of an object by certain sensors. This can also be formulated as a target outcome for detectors (for instance, “cause detectors to output no detection for object X” versus “cause detectors to output a confident detection of object Y” versus “ensure object Z is always detected with high confidence by friendly detector”). In many implementations, the operator explicitly selects between a stealth mode and a decoy mode. A variation of the decoy mode covers the visibility enhancement use case, where the pattern's goal is to produce a true detection (but by friendly systems).

Another input the input processing module 110 may receive is environmental context. Environment context may include information about the operational environment in which the pattern or signal will be deployed. This may include the background scenery or terrain type (e.g., forest, urban cityscape, desert, open ocean, etc.), typical colors or textures in that environment, lighting conditions (e.g., daylight, nighttime with artificial lighting or IR illumination), weather conditions, and other context that could affect both the sensor appearance of an object (or physical target) and what constitutes a plausible pattern. The user might input an environment profile (e.g., “dense jungle” or specific location data), or the system might automatically gather environmental data (for instance, retrieving satellite imagery, spectral measurements of foliage, sample background photographs) to inform pattern design. For digital deception cases (where the “object” might be injected into sensor data streams), the “environment” could be properties of the sensor feed itself (e.g., camera resolution, typical image noise and compression artifacts, sensor perspective).

The input processing module 110 may receive a sensor and threat profile. This profile may include specifications of the sensing modalities and AI detectors that the adversary (or conversely, the allied observer) is expected to use. This may include a list of sensor types to consider (visible-light cameras, long-wave infrared cameras, near-IR night vision, LiDAR depth sensors, radar, acoustic microphones, etc.) and possibly specifics about the detection models or algorithms of concern. For example, the user could specify that the adversary employs a certain class of vision model (like a YOLO-based object detector for vehicles), or that one should assume state-of-the-art image classifiers if exact models are unknown. The threat profile informs the configuration of the detector ensemble used in the simulation stage (described below). In one use case, the operator might indicate that an enemy uses a specific AI-enabled drone with an IR camera and a known vehicle classifier; the system will then ensure it includes similar detectors (or surrogate models representing that capability) in its evaluation loop. In a visibility enhancement scenario, the “threat” profile might actually be the profile of the friendly detection system we want to impress (for instance, the vision algorithm in self-driving cars, which the pattern should be highly visible to).

The input processing module 110 may further receive deployment constraints and preferences. This may include practical constraints for the pattern or signal deployment. This might include physical constraints like the surface area available for applying a pattern, allowable colors or materials (for safety, regulatory, or branding reasons), or restrictions such as “do not cover these specific parts of the object.” For decoys, it might include resource limits (e.g., “we have an inflatable decoy structure of size X and an IR heating device of power Y available” or “the decoy must be portable and deployable by one person within 5 minutes”). Operator preferences could also be captured, such as whether subtlety to human observers is critical (in stealth mode it usually is, whereas in some decoy cases it might be less important if humans are not expected to observe the decoy directly). Another example is whether the pattern should be persistent/reusable or one-time-use. These inputs allow the system to honor real-world constraints and tailor solutions that are not only algorithmically effective but also practically deployable.

The input processing module 110 may receive optional optimization criteria that may correspond to specific metrics or weighting factors for the optimization objective. By default, the system will consider machine detection probability as the primary metric (to minimize for stealth or maximize for decoy), possibly with a secondary metric for human observability (to minimize conspicuousness to humans). However, the user or mission parameters might demand weighting certain sensor avoidance more heavily than others (e.g., “it's more important to be invisible to thermal cameras than to visual cameras for this scenario”) or might require achieving a certain confidence boost in a decoy effect. The system can accept such criteria to adjust its internal scoring function accordingly.

Once these inputs are provided, the input processing module 110 may perform preprocessing such as normalizing and validating the data, constructing an initial digital representation of the scenario, and selecting appropriate internal models. For example, if no detailed 3D model of the target object is provided, the system might generate a proxy model procedurally or retrieve a similar shape from a library, so that there is a geometric basis for simulations. If the user specifies only a target class for a decoy (say “tank” with no physical model given), the system can load a generic tank model and its typical sensor signatures as the basis for decoy generation. Additionally, based on environment input, the module can load background textures or sensor data profiles to use during simulation.

In some embodiments, the inputs and potential constraints (e.g., practical constraints or user preferences affecting the generated pattern or signal; it also may include physical constraints such as the surface area or shape available for applying a pattern, allowable colors or materials, or restrictions like “do not cover or alter these specific parts of the object) as described may be processed as a vector value and may be stored in a database. The vector value may be used for comparison against other vector values to identify a closest fit to a desired pattern. As further described below, vector value may be adjusted based on a feedback process as described below where the inputs and constraints may be updated based on weighting factors. That updated vector value may be used to compare against previously stored vector values when selecting updated patterns based on the feedback loop described below.

### Multi-Modal Scene Simulation (Digital Twin Environment)

After input processing, the system enters the scene simulation stage that includes processing of the pattern generation module 115 and the simulation module 120. Using the inputs and preprocessing from the input processing module 110, the pattern generation module 115 generates 215 an initial set of candidate patterns for use a cloaking (or disguise (e.g., camouflage) pattern for a target object. Here, a digital twin of the target object and its environment may be created to evaluate the generated candidate patterns under real world conditions within which the object may be placed. Each candidate adversarial pattern or signal configuration generated by the system is applied in this virtual scene to test its effectiveness before any physical deployment is attempted.

For a visual cloaking pattern, e.g., a camouflage pattern to apply onto a target object, this means the pattern texture is mapped onto the 3D model of the target object, for example, wrapping the pattern image around the surface of a vehicle or person model. The generated model from the pattern generation module 115 is sent to the simulation module 120 and applied 225 onto the target object in a simulated environment that reflects the anticipated real world deployment context. For example, if the target is a military vehicle meant to hide in forested terrain, the simulation might place the 3D vehicle model with the candidate pattern into a virtual forest scene with foliage, variable lighting (e.g., dappled sunlight through trees, or night-time conditions if relevant). If the scenario is an urban setting, the model might be tested against various city backgrounds (e.g., building facades, roads) and lighting conditions (e.g., day vs. night, streetlights, etc.). The simulation may render multiple viewpoints, for example. different camera angles, distances, and/or sensor zoom levels, to ensure the pattern's effectiveness is robust from different perspectives and not just a single viewpoint trick. This helps increase the difficulty of detection by adversarial AI systems, e.g., adversarial AI driven image recognition systems.

For non-visual modalities, the simulation module 120 may be configured to simulate a sensor signature of an object in those domains. For example, in an infrared (Thermal) simulation the system may simulate a heat emission profile of an object. If the object is a vehicle, the simulation might incorporate expected engine heat, exhaust heat, and the ambient temperature context. A candidate adversarial design might include not just a visual pattern but also specifications for thermal masking or emissions blocking, for example, as regions where IR-insulating material should be applied, or active cooling/heating elements in an object that is a decoy. The simulation would generate a synthetic thermal image of the scene, showing how the pattern and any thermal measures may affect a heat signature of the object. Here, the configuration increases the difficulty of detectability from, for example, adversarial AI system seeking thermal or heat detection to locate an object.

For radar simulation, the simulation module 120 may be configured to simulate a radar cross-section (RCS) model of the object and adjust it based on any adversarial modifications in the design, for example, placement of reflective patches or radar-absorbent material in a camouflage pattern. It may simulate radar pulses and compute the return signal, or use analytical models to estimate how detectable the object is with the pattern. The simulation might simply evaluate whether the pattern's prescribed modifications (like adding radar reflectors in certain spots for a decoy, or radar-absorbing coating for stealth) would alter the overall RCS significantly. Here, the configuration increases the level of detectability from, for example, adversarial AI radar systems.

For LiDAR simulation the simulation module 120 may be configured to simulate the point cloud or depth map that a LiDAR sensor would produce when scanning the scene. If the adversarial pattern involves 3D geometric alterations in which those modifications are reflected in the simulated LiDAR data, for example, attaching protrusions, covers, or shape-masking props to the object as part of the design. The simulation may check if these alterations break up the recognizable shape of the object or create misleading depth readings. For decoys, if the system suggests a configuration of multiple objects (e.g., a cluster of small drones) to create a composite LiDAR signature, the simulation may generate that point cloud. Here, the configuration increases the level of detectability from, for example, adversarial AI LiDAR systems.

For acoustic or other sensors the simulation module 120 may be configured to simulate approaches to apply to sound or other modalities if relevant. For example, if the scenario involves acoustic stealth or decoy, which may involve making a vehicle quieter or generating an artificial (or fake) engine noise elsewhere, the simulation may model the noise profile of the object in the environment and adjust it based on any adversarial audio elements of the design. Here, the configuration increases the level of detectability from, for example, adversarial AI acoustic systems.

The simulation module 120 may use conventional physics models and sensor models to render how the object with a given adversarial pattern would appear to each type of sensor. The result is a set of synthetic sensor data (images, heat maps, LiDAR point clouds, radar echo profiles, audio recordings, etc.) that show the effectiveness of the candidate pattern or signal in a controlled virtual experiment. Critically, this simulation stage allows rapid, safe evaluation of many pattern variants without needing to physically produce each one. It approximates the adversary's view (or the relevant machine perception) under representative conditions.

In some embodiments, this simulation can leverage sophisticated rendering engines (e.g., video game engines or custom sensor simulators) to produce highly realistic sensor outputs, optionally incorporating randomness or noise. For example, the simulation may add typical sensor noise, simulate slight motions (like a person breathing or leaves rustling) to test pattern robustness, or vary environmental parameters (lighting changes, different backgrounds) across multiple runs. The simulation can run each candidate pattern through all relevant sensors in the ensemble, producing a comprehensive picture of performance.

### Detector Ensemble and Adversarial Evaluation

Coupled with the simulation module 120 is the detector ensemble module 125. The detector ensemble module 125 contains a suite of object detection models corresponding to the adversary (or target observer) perception capabilities. This ensemble may include, for example, an art image recognition neural network (or several diverse models) for visible-spectrum detection, trained to recognize the class of object in question (e.g., person, vehicle, etc.). an infrared (thermal) object detector or anomaly detector for simulated heat images. a LiDAR-based classifier or shape detector for 3D point clouds or depth maps, a radar signature classifier, if applicable, that could be a model that classifies objects based on radar return profiles. The ensemble also may include any other AI model that corresponds to sensors of interest, such as an acoustic event classifier (if sound is in scope) or multispectral fusion algorithms that combine sensor inputs.

The models receive the simulated sensor data of the scene with the candidate pattern applied from the simulation module 120 so that detector ensemble module 125 may execute (or run) 230 a process to detect or classify the target object. Because the system is using an adversary human, system, or sensor perspective it is seeking to influence, these models are evaluating detection of the object as though no countermeasures are applied. The adversarial pattern job is to either cause no detection when in a stealth mode or to cause a false detection of something that is not actually there when in a decoy mode.

During evaluation, the detector ensemble module 125 of the system computes 235 performance metrics for the adversarial pattern. For example, outputs are recorded for the given adversarial pattern and stored in a storage (e.g., database and/or table in a memory or long-term storage). The outputs may include, for example, a binary detected/not-detected flag, a confidence score for detection, a classification label (e.g., “person” vs “background”), and localization data like bounding boxes or segmentation masks that may indicate whether the detector identified where the object is or may have run into confusion. For example, a visual-spectrum AI model might normally output “person detected with 95% confidence” for an uncamouflaged person; but with a candidate adversarial outfit, it might output “no person detected” or misclassify the person as some benign object. A thermal detector might output a very low confidence of a human presence if the heat pattern is disrupted. In decoy mode, success would be indicated by detectors falsely reporting a target: e.g., the AI vision model says “tank detected at coordinates X” in an image where in reality there is only a canvas with a pattern on the ground.

The outputs are aggregated into a fitness score or set of metrics for the candidate pattern. In one embodiment, the system defines a composite stealth score that penalizes any detection above a certain confidence by any model (e.g., the lower the score, the better the stealth). Alternatively, a multi-objective approach may be used: for stealth, perhaps the metric is the highest detection confidence among all models (aiming to minimize that); for decoy, perhaps the metric is the detection confidence for the fictitious target by the most sensitive model (e.g., aiming to maximize that). A scoring function may be configured depending on mission priorities, but the key is that it quantitatively measures how well the pattern met the objective against the ensemble of detectors.

Optionally, the evaluation phase can include a human-visual plausibility check or other secondary criteria. Because some adversarial patterns might achieve machine fooling by introducing strange artifacts, the system may include checks to ensure the pattern remains within acceptable bounds for real-world use. For instance, the system can analyze the candidate pattern's appearance for conspicuous features: this could be a heuristic (e.g., “does the pattern have extremely high-contrast edges or unnaturally bright colors?”) or a dedicated model (e.g., a neural network trained to classify images as “natural” vs “suspicious”). Patterns that are likely to alert human observers can be filtered out or given a penalty in the fitness score. Similarly, for decoy patterns that might be observed by human allies or enemies, the system can enforce that the decoy looks plausible to humans at least under expected viewing conditions (for example, a fake tank decoy should visually resemble a tank shape/color at distance if humans might also see it). By incorporating such constraints, the system avoids solutions that “cheat” the AI at the expense of being obviously fake to a human.

From the processing through the detector ensemble module 125, every candidate pattern may be assigned an associated performance score and/or a set of metric values that indicate how it fared against the simulated detectors and any other criteria. This information is then fed into the optimization core module 130 to guide a next iteration of pattern refinement.

### Adversarial Pattern Generation Techniques

The optimization core module 130 is configured to provide as an adversarial pattern generator and drive a refinement loop. It automatically searches for an optimal pattern or signal through iterative improvement, essentially “training” the camouflage or decoy via trial and feedback. The optimization core module 130 determines 240 whether the pattern meets a criteria for finalization. If not, the optimization core module 130 is configured to trigger a feedback look to adjust 245 (or optimize) the pattern parameters through an iterative 250 loop that may start with the generation of initial candidate patterns. It is noted that the disclosed configuration is not limited to a single algorithm for this optimization. Rather, it encompasses any suitable technique for iteratively adjusting the pattern based on detector feedback. Once the optimization core module 130 determines 240 that criteria is met 240, the process proceeds with finalizing 255 the optimized pattern.

Some example approaches that may be used alone or in combination with this iterative process include evolutionary algorithms/genetic programming. Here, the system treats each candidate pattern as an individual in a population. After each evaluation round, patterns receive fitness scores as described above. The optimization core module 130 selects the fittest candidates and uses them to produce a new generation of patterns by applying an evolution operation. The evolution operation may comprise a crossover operation that recombines features from two or more parent patterns and a mutation operation that makes random perturbations to a pattern. For example, two camouflage patterns that may have been identified as effective may now be “crossed” by blending or swapping regions of their texture, potentially creating a hybrid that inherits good qualities of both. Additionally, small random alterations might be introduced to explore the space (mutations). Over successive generations, the population of patterns ideally improves its performance, e.g., patterns become increasingly adept at evading detection or inducing false detections. This evolutionary loop continues until a stopping criterion is met, such as a pattern achieving a desired fitness or a maximum number of generations being reached.

Another approach includes reinforcement learning (RL). Here, the pattern generation may be framed as a sequential decision-making process, where an agent, e.g., a neural network, incrementally modifies the pattern and receives a reward based on the detection outcome. In this setup, each “action” could be an alteration to the pattern, for example, tweaking a region's color, adding a shape, etc., and the reward is high when the detectors are fooled. By way of example, for stealth a reward could be proportional to lack of detection while for decoy a reward may be proportional to success of false detection. Techniques like policy gradient methods or Q-learning can be employed, where the agent learns through trial and error to construct patterns that maximize its cumulative reward. Essentially, the system learns a strategy of how to paint or configure the pattern step by step, guided by feedback from the detector ensemble.

In certain embodiments, the optimization core module 130 may employ a reinforcement learning (RL) agent to refine the adversarial pattern through trial-and-error interaction with the detector ensemble. The RL agent may determine a space includes information about the current pattern and detection feedback. For example, the RL agent may observe (e.g., identify a state of) parameters or features of a pattern along with detection confidence scores or other outputs from the object detection models indicating detectability of the target.

The RL agent action space may encompass a set of permitted perturbation operations that may alter the pattern, for example, adjusting color or texture in a region of the pattern, shifting or adding pattern elements, applying noise or other visual perturbations, or otherwise modifying a configuration of the adversarial pattern as applied on the target object. After each action, the agent evaluates the result through the detector feedback and computes a reward (e.g., a score or a descriptive value) based on the change in detectability. For example, the reward is higher when the modification causes a drop in detector confidence or success rate in identifying the target (indicating improved camouflage effectiveness), or in a decoy mode, when the modification increases the likelihood of a false positive detection of a nonexistent target. Over successive iterations, the RL agent learns a policy that maximizes this reward signal. This allows the RL agent to discover an optimal sequence of pattern adjustments that significantly reduces the detectability (or achieves the desired deception outcome) of the target by an adversary machine perception system. This reinforcement learning approach allows the system to autonomously evolve highly effective adversarial patterns (e.g., camouflage or signal), with the agent continuously improving the pattern by observing detection responses, taking pattern-altering actions, and reinforcing those actions that yield better stealth or deception performance.

Yet another approach is gradient-based optimization. If the detector models are differentiable and if the entire simulation pipeline can be approximated or made differentiable, the system can directly compute gradients of a loss function with respect to the pattern's parameters. This is analogous to classical adversarial example generation in the digital domain, where one computes how a pixel change would affect the detector's output. Here, one might use a differentiable renderer for the simulation so that the effect of a pixel in the pattern on the detector's confidence is traceable. The system can then adjust the pattern in the direction that reduces detectability (for stealth) or increases it (for decoy), using methods like gradient descent/ascent. Constraints and regularizations are applied to ensure the pattern remains within the realm of physically realizable changes, for example, avoiding colors that cannot be printed or textures that are too high-frequency to produce in reality.

Another approach is a combinatorial or heuristic search. In some cases, such as for non-visual modalities or simpler pattern parametrizations, more straightforward search methods may be used. For example, if the adversarial design problem is to place a small set of reflective decals on an object to confuse radar, the search space might be combinatorial, which may be a subset of possible locations to place reflectors. A heuristic or brute-force search might try combinations or use optimization techniques like simulated annealing or integer linear programming to find the best configuration.

Often, the system can employ a hybrid of the above techniques. For instance, a generative model (such as a GAN) could be trained beforehand to produce “reasonable” camouflage patterns, and the optimization core then uses that model to propose initial candidates or as a mutation operator. A GAN might treat the detector ensemble as an adversary during its training (a form of generative adversarial training), resulting in a generator network specialized in producing adversarial patterns. Alternatively, the system might run a gradient-based refinement on top of patterns initially found by an evolutionary algorithm-combining global search with fine-grained tuning.

Regardless of approach, the optimization core module 130 drives an iterative feedback loop 250 for the system. An example iteration may be as follows. The pattern generator module 115 produces (e.g., generates or retrieves via a search of a library) one or more new candidate patterns, either randomly, via learned model output, or by modifying previous successful patterns. By way of example, a multidimensional vector and may be used in defining adversarial patterns and the multidimensional vector may be stored as a vector value in a database. The selection of a candidate vector for production may be based on a vector value corresponding to the defined vector.

These produced candidates are passed to the simulation module 120 and detector ensemble module 125 as described above to yielding performance scores. The optimization core module 130 updates its strategy or the candidate set based on the results. This could mean updating the weights in a neural network generator (if using backpropagation or RL), choosing which patterns become “parents” for the next genetic generation, adjusting an RL policy network parameters, etc. The loop repeats with generation 220 of improved candidates that are cycled through the analysis process. Over many cycles, the system “converges” towards an optimized adversarial pattern design. This adaptive loop continues until an optimized adversarial pattern (or set of patterns) is obtained that meets 240 a predefined criteria to move towards finalization 255 of an optimized pattern. An example of predefined criteria that is met may include, for example, one or more of achieving a detection probability below a threshold for stealth, or above a threshold for decoy success, reaching a maximum number of iterations/generations, or observing that improvements have plateaued (convergence).

Through this process, the system effectively learns an adversarial solution against the detectors deployed by adversaries. As machines sparring against each other, the pattern generator module 115 is trying to “beat” the detection models, which themselves represent the adversary perception capabilities, which may be machine, human, or combination. The result of many iterative trials is often a pattern design far more complex and effective than a human would devise, leveraging subtle perturbations that exploit weaknesses in the AI models. Importantly, because the system considers a multi-modal ensemble of detectors simultaneously, it can find solutions that confuse all included sensors at once, thereby avoiding the pitfall where a pattern only fools one modality but is glaringly obvious in another. For example, the optimization will generally not settle for a solution that only fools the camera but leaves an obvious thermal signature; it will continue refining until the thermal detectability is also reduced or balanced with acceptable trade-offs. The outcome is an integrated adversarial design that considers the full spectrum of detection methods likely to be employed.

Additionally, the optimization can incorporate randomness and seek robustness to avoid overfitting to the specific simulated conditions. The final output might be a pattern that works under a range of angles and backgrounds, or the system might output multiple alternative pattern solutions that all meet the requirements (so that users can, for instance, deploy slightly different patterns on different units for security through diversity). In some embodiments, the system ensures that no single static pattern becomes the sole solution used universally, since a static pattern could eventually be learned and countered by adversaries if encountered repeatedly. Instead, it can generate variants on the fly or on demand that all achieve the goal, providing a moving target that is much harder for the adversary to learn or predict.

### Output Compiler and Deployment Preparation

Once a digital optimized adversarial pattern or signal configuration is obtained from the core optimization core module 130 (or optimization module 130), the system proceeds to prepare a finalize 255 optimized pattern as an output for real-world deployment. Specifically, the optimized pattern is sent to the output compiler module 135. The output compiler module 135 is configured to process the digital pattern design and converts it into a form that is usable by end-users, technicians, or devices to apply 260 the pattern to a physical (or real) object. The output compiler module 135 bridges the computer-optimized design and a tangible, deployable artifact.

For adversarial visual patterns (e.g. a camouflage texture or a decoy graphic), the output may be one or more image files or print files that correspond to the physical medium needed. For instance, if the pattern is to be applied as a printed wrap or paint, the compiler may generate high-resolution image files suitable for printing. It may perform panelization/tiling of the pattern, for example, splitting a large pattern into segments that fit standard printer dimensions or material sizes, while ensuring continuity at the seams. Each tile or panel may be labeled (e.g., “Panel A-apply to left side of object, Panel B-apply to front”) along with a layout diagram. The output compiler can produce a flattened UV map or stencil if the target object has a complex 3D shape to essentially unwrapping the 3D surface into 2D printable sections so the pattern may be applied in a geometrically correct way. This might involve providing templates that show exactly where each piece goes on the object, possibly including alignment marks or fiducial markers to help position the pattern correctly when installing it on the object's surface. If the pattern is meant for a garment or netting, the output might be sewing patterns or fabric print layouts.

For adversarial electronic or emissive signals (e.g., an infrared emission pattern, radar spoofing signal, or acoustic output), the output could be a device configuration or executable control script. For example, if the solution involves driving a set of thermal emitters according to a certain spatiotemporal pattern to mimic an engine's heat, the compiler will output the control signals (waveform or sequence of on/off commands) for those emitters. If a radar decoy effect is achieved via an RF transponder, the output might include the frequencies, modulation scheme, and timing that the transponder should use. Essentially, the output compiler translates the optimized “signal pattern” into low-level instructions or data that can be loaded onto the appropriate hardware (be it an IR lamp controller, a speaker system for sound, a radio transmitter, etc.).

If the adversarial solution includes physical 3D components or surface modifications as part of the design (for instance, adding certain protrusions, ridges, retroreflective shapes, or acoustic baffles to the object), the output module can generate CAD files or 3D printable models for those components. For example, the system might determine that adding a particular 3D shroud around a camera lens can help hide it from LiDAR; the output could be a custom 3D model of that shroud, ready for fabrication on a 3D printer or CNC machine. These components would come with instructions on how to attach them to the target object.

In addition to the pattern files or device instructions, the output compiler module 135 may be configured to generate documentation or instructions for the deployment process. This can include: a human-readable assembly guide for technicians (step-by-step instructions on how to apply the printed panels or configure the devices); a list of recommended materials (e.g., specific vinyl types, paint color codes, printer settings, adhesive types) to achieve the design as intended; and any safety or operational notes, for example, “the decoy RF emitter should not exceed X power for regulatory compliance” or “pattern effectiveness may degrade if viewed under ultraviolet light”. The documentation ensures that the end-users understand how to correctly implement the pattern and are aware of any limitations or precautions.

The output compiler module 135 is configured to faithfully translate the digital optimized design into a deployable format, accounting for the realities of the medium and installation. It accounts for the shape of the object including providing distortion-corrected patterns so they appear correct when applied on curved surfaces, the scale including ensuring the output graphics are at the correct physical size and resolution, and any special integration needs including cut-outs for sensors or attachment points, connectors for emitter devices, etc. By doing so, it aims to ensure that when the pattern is actually deployed, it appears and and functions as it did in simulation.

In some embodiments, the output compiler module 135 may interface directly with manufacturing or deployment hardware to streamline the process. For example, after generating the pattern files, the system may automatically transmit them to a connected large-format printer or instruct a robotic painting arm to begin applying the pattern. If the deployment medium is a digital display (e.g., an e-ink screen wrap on a vehicle), the integrator module 140, which is further described below, may directly update the display with the pattern images. For signal emitters, the system could transmit the control script to the device's firmware or microcontroller over a network so that it starts emitting the pattern immediately. In this way, the invention supports not only the planning and design of adversarial patterns, but also the automated execution of those patterns on the target platform.

The output compiler module 135 may record the generated pattern and associated data in a database or library for future reference. It can store the pattern design along with metadata about its intended context and achieved performance. This archive supports continuous improvement and reuse: if a similar scenario arises again, the system can retrieve prior solutions as a starting point or avoid designs that are known to have limitations.

### Deployment Integrator and Device Interface

Once the output files and instructions are prepared, the deployment integrator module 140 is configured to assist with applying 260 the finalized generated adversarial pattern in the physical world and manage the deployment logistics. In some embodiments, the output compiler module 135 and the integrator module 140 functions are closely related or integrated.

The integrator module 140 is configured to be device-agnostic and extensible, supporting deployment to a wide array of output technologies. It establishes a standard interface for pattern intent input (the high-level pattern specification coming from the engine), so that any pattern generation engine can plug into the deployment pipeline, and conversely, a variety of output devices can be driven without altering the core engine's output format. This decoupling means the same optimized pattern specification can be applied to different hardware setups by the integrator module 140 handling the details for each. The integrator module 140 is configured to include a display and observe module 150, a feedback module 155, and field sensors/capture module 160.

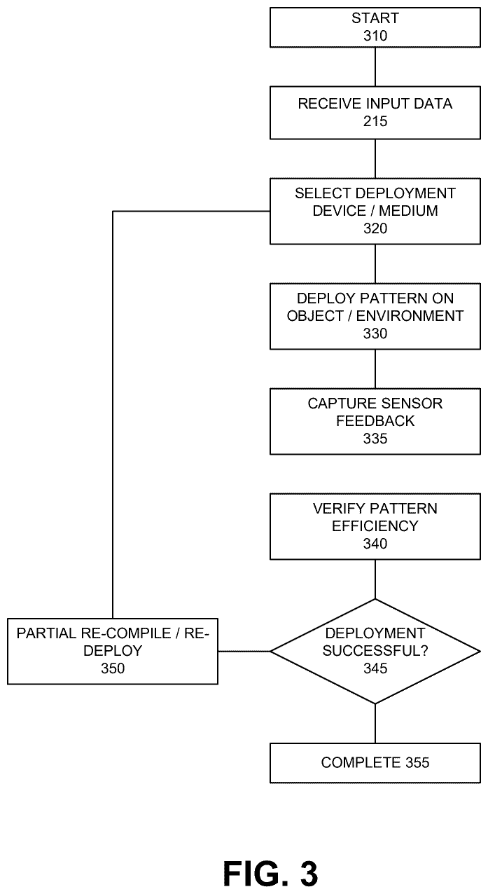

FIG. 3 illustrates a process for deploying an example optimized adversarial pattern onto a target in accordance with one embodiment. The process starts 310 with the integrator module 140 receiving 315 input data corresponding to the target object, including for example, what the target object is, its objective, the environment for deployment, and/or its sensor profile. Based on the input received, the system selects 320 a deployment device or medium to prepare patterns to output that will be applied 260 to the target object. Examples of supported outputs from the integrator module 140 include, but are not limited to traditional print media (vinyl printers, industrial printers for large fabrics or wraps), robotic painting systems (for directly painting patterns onto surfaces), emissive display panels (flexible e-ink sheets, OLED or LED arrays that can show dynamic patterns on an object's surface), digital projectors (for projecting patterns onto objects or terrain), radio frequency (RF) transmitters or phased arrays (for radar/RF signal patterns), thermal heating element arrays (for infrared patterns), and other specialized hardware like vapor or aerosol projectors (to create obscurant clouds with certain signatures). For instance, a single platform (the Integrator) can prepare patterns for a variety of platforms: one day it might output printable camouflage for a vehicle, the next day it might output a configuration for a set of IR lamps on a drone. The modular design of device drivers of the integrator module 140 allows it to incorporate new device types as technology evolves or new use cases emerge.

For each chosen medium, the display and observe module 150 of the integrator module 140 is configured to determine what is displayed and observed regarding effectiveness of an adversarial pattern applied to a target object in an environment. The configuration may automate the formatting and alignment tasks for application of the adversarial pattern onto the target object. In some embodiments, tasks may overlap with what the output compiler module 135 processes. However, the integrator module 140 is configured to carry them out in hardware or final file formats. This may include transforming 325 the generated adversarial pattern for the device that will create the pattern for application. For example, it may include print tiling, which may involve compiling, splitting, and calibrating large images into printable sheets with proper overlaps and registration marks for alignment. It handles display mapping when the pattern is destined for multiple screens or panels, adjusting for differences in resolution, arranging image segments to corresponding panel coordinates, and compensating for bezel gaps if needed. For emissive arrays or multi-device outputs, it ensures each segment of the pattern is assigned to the correct device ID or channel. The integrator inserts and utilizes registration marks or fiducial references both in the digital files and in the physical assembly to guide precise placement. During deployment, it can provide instructions like “align mark A on panel 1 with mark A on panel 2” to achieve seamless continuity of the pattern across joins. By automating these formatting and alignment steps, the system reduces human error and ensures that the adversarial pattern, once assembled or displayed, matches the intended design with pixel-level accuracy.

The field sensor/capture module 160 of the the integrator module 140 may be configured to capture data corresponding to a deployment of the adversarial pattern with the target object in the real-world deployment environment. Further, the feedback module 155 of the integrator module 140 may be configured to capture this data and generate feedback for additional adjustments as a part of the transformation 325 process. For example, if the pattern will be applied to a curved or irregular surface, the integrator can pre-distort the generated adversarial pattern in the opposite way, so that when it's laid onto the surface, it appears correct to an external viewer (this is similar to how map projections work, or how one might pre-warp an image before projecting it onto a 3D shape). An example is deploying an adversarial pattern on an aircraft fuselage: the system can distort the pattern in the print files such that once the curved fuselage is wrapped, the pattern's intended geometry is restored when viewed head-on. The integrator module 140 also may be configured to adjust output intensities or other parameters to meet safety and regulatory constraints. For instance, if deploying via an array of high-power LEDs as an active decoy, the integrator will ensure brightness and flicker frequency stay within eye-safety limits and do not interfere with other equipment's radio frequencies. If an adversarial pattern is meant to blend at night, it may adjust luminance differently than for daytime use. If a radar emitter decoy must comply with emission regulations, it will cap the power or use allowed frequency bands. Environment and compliance related tweaks are integrated into the final deployment instructions.

When the adversarial pattern and device instructions are ready, the integrator module 140 is configured to drive the output devices, e.g., transmit instructions for operations to generate the output desired from the process described. For a printer, it might spool the tiled image files to the printer in the correct sequence and handle color calibration by sending color profiles. For a projection system, it may configure the projector's position (with help of a calibration routine) and feed the image or video signal at the right resolution and warping. For an array of emitters (like a grid of infrared LEDs on a panel), it will communicate with the microcontroller or control software of that panel to upload the pattern settings. The integrator module 140 also may coordinate multiple devices simultaneously: e.g., instructing several drones each equipped with emitters to position themselves in a formation, then timing their signals collectively to produce a composite decoy signature in the environment.

### Verification and Feedback Subsystem

The disclosed configuration beneficially allows for integration of a post-deployment verification and feedback module 165. Once the adversarial pattern is deployed 330 on the object or emitted into the environment, the system employs sensors to capture 335 data on the actual deployment result and verify 265, 340 its effectiveness by whether it meets the intended performance criteria. Once the pattern is applied or active, the system analyzes the object using the relevant sensor modalities. For example, if the goal was visual camouflage, the system may use one or more cameras to take images of the object from various angles against the real background. If thermal stealth was part of the goal, a thermal camera may be used to capture a heat signature of the object after applying any thermal elements. If a radar decoy was deployed, a radar receiver may be deployed to measure the radar returns from the area. These verification sensors may correspond with those used in simulation module 120 and/or detector ensemble module 125. Moreover, AI detection models that may be deployed in real-time are configured to analyze the sensor feed in real time by using an output of the verification feedback module 165 as a feedback signal 170 back into the process through the pattern generation module 115.

The verification feedback module 165 is configured to automatically analyze the captured data to determine 345 if the adversarial effect is present. It may iterate 350 the detection tests to recompile and redeploy the outputted adversarial pattern using the real-world data. It may be configured to run the same ensemble of detectors on the images of the deployed object to see if it is detected or not. It compares the outputs (or low-level data like color values, emitted signal strengths) to the expected results from the design. The system generates a verification report documenting the findings: for instance, “Under visible light camera test, object not detected by Model X (confidence<0.1) as intended. Under thermal camera, a faint signature was still observable at 0.3 confidence, slightly above target of 0.2,” etc. Any discrepancies between the intended performance and the measured performance are flagged.

If the verification indicates a significant deviation, for example, maybe one panel of the printed pattern was misaligned causing a detectable feature, or the actual color printed was slightly off hue, the system may initiate a correction cycle. The correction cycle is configured to adjusting parameters that may be misaligned and re-deploying a part of the pattern. For instance, if a printed segment's color was off, the system might recalibrate the printer or reprint that panel with a corrected color mix. If a projector's alignment was off, it can refit the warping based on the error measured (some systems do this by detecting the projected image's fiducials with a camera and adjusting accordingly). If an LED emitter's output was weaker than expected in certain elements, it may increase the drive current within safe limits and test again. This iterative correction ensures that the final deployed product is as close to the optimized design as possible. It is noted that the verification report and any sensor data collected may be saved as part of the deployment record to enable traceability. The record may be used to later show what the pattern looked like and how it performed, which might be valuable for after-action analysis or further research. Once verification completes and the generated adversarial pattern is deployed the process may complete 355 (or end 270).

### Real-Time Edge Deployment and Fleet Adaptation

In advanced embodiments, the disclosed configuration supports real-time adaptation and federated updates across a fleet of devices or platforms. This means the system is more than a one-shot design-and-deploy tool. It may continue to operate in the field and improve the patterns on the fly or across multiple deployments. For example, consider a scenario where a vehicle is equipped with an electronic ink display skin that can change its pattern dynamically. The adversarial optimization engine (perhaps a scaled-down version) could run on an on-board computer of that vehicle. As the vehicle moves through different environments (e.g., from forest to open field to urban area), the system can periodically generate slight updates to the displayed pattern to maintain optimal camouflage under the new background conditions. If it senses, say, that an effectiveness of a particular adversarial pattern is dropping, for example, if an adversary sensor started picking it up, it could trigger a rapid re-optimization and update the pattern in near-real-time. Advances in edge AI hardware make this feasible, running the simulation and detector models on portable devices. If true real-time generation is too slow, the system could fall back to a library of pre-optimized patterns for typical environments and just switch between them, which is still an adaptive behavior.

The system also contemplates continuous learning through field feedback. Suppose multiple units (e.g., vehicles, drones, soldiers'suits) are all using adversarial patterns generated by the system. These units can form a federated network sharing information about their encounters. If one unit's camouflage was partially foiled (e.g., an enemy managed to detect it with a new sensor technique), that data can be shared back to a central server or peer units. The central optimization engine could incorporate that new data (maybe adding the enemy's updated detector into the ensemble) and evolve a new pattern variant that counters it. It could then push an update to all units in the field, so they can update their patterns (assuming they have dynamic display capability or can at least swap to a new pre-printed cape overnight, etc.). In the case of decoys, if an adversary learns to recognize a decoy pattern after a while, the system can generate a new decoy pattern that the adversary has not seen, and disseminate it to all decoy devices.

This networked approach creates a moving target defense: the adversarial patterns are not static but continuously evolving in response to adversary adaptations. Even if the adversary develops counter-countermeasures (like retraining their AI to recognize a specific pattern), the system will likely have moved on to a new pattern by then or can do so as soon as a weakness is observed. Secure communications would be used for these updates to prevent the adversary from intercepting pattern data or interfering with the pattern update process.

By supporting real-time edge operation and fleet-wide learning, the invention turns what could be a one-time trick into a sustainable capability. Stealth and deception measures become an ongoing service: continuously monitoring, updating, and staying one step ahead of evolving detection threats. Over time, this adaptive loop enables outputs from the system to be difficult to counter, as they do not remain constant long enough for the adversary to reliably catch up.

### Federated/Distributed RL in Fleet Deployments

For deployments involving multiple assets or a fleet of platforms, the reinforcement learning-based optimization can be implemented in a distributed or federated manner across the network of devices. In such an embodiment, each asset (e.g., each vehicle, drone, or other camouflaged unit) runs a local instance of the RL optimization agent at the edge, allowing it to fine-tune and adapt its own adversarial pattern in real time based on local sensor inputs and detector feedback. These local RL agents can periodically share their learned policy parameters or summary performance metrics with a central server (or with each other in a peer-to-peer network). The central system aggregates updates from the individual agents and refines a global policy, which is then synced back to the edge devices so that each asset updates its local model or policy. This federated reinforcement learning scheme enables the entire fleet to benefit from the experiences of each individual unit without requiring raw sensor data to be transmitted from the field. In practice, if one asset encounters a new or updated detector threat and learns an effective pattern adjustment through its local RL process, that knowledge (in the form of policy updates) is shared and quickly disseminated to all other units. Consequently, the camouflage patterns across the fleet continually co-evolve and improve in a coordinated fashion, ensuring that every deployed asset remains up-to-date and effective against the latest detection techniques observed by any member of the fleet. This networked learning approach provides a robust, adaptive defense: the more the system is used across diverse conditions, the smarter and more resilient the camouflage policies become for all connected assets, creating a moving target that adversaries struggle to counter.

### Example Use Cases

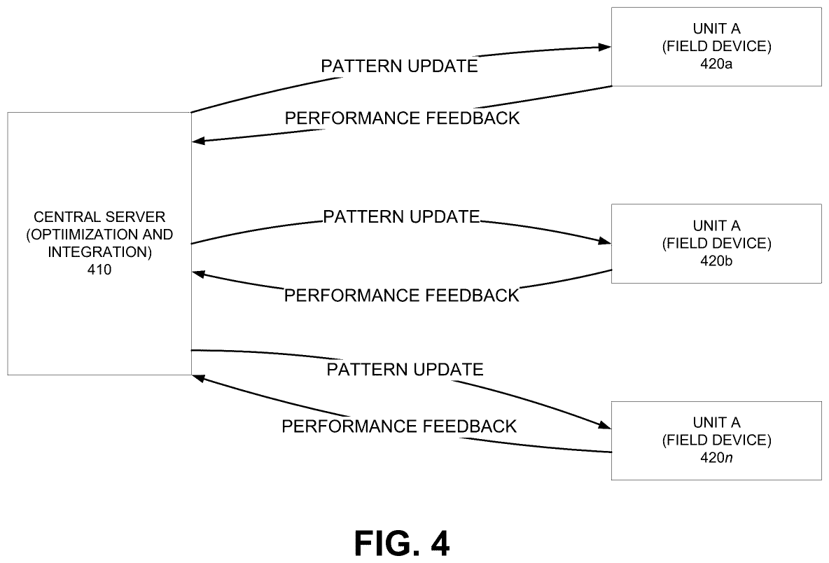

To further illustrate the breadth of applications, a few example use cases are summarized and also depicted conceptually in FIG. 4 for multi-unit deployment. FIG. 4 illustrates an operational flow of an example deployment scenario with multiple distributed devices receiving adversarial patterns from a server system in accordance with one embodiment. In this example deployment scenario, a central server 410 may include the optimization core module 130 and the integrator module 140. Using a pipeline are described herein, a pattern update may be deployed to one or more field devices 420a to 420n (or units) (generally 420; illustrated are three field devices 420a-420c). As the patterns are deployed, the field units 420 provide performance feedback corresponding to the effectiveness of the generated pattern against adversarial AI systems that are seeking those field devices through their systems.

Continuing the examples of what may be a field device, in one example it may be a personal stealth wearables. It may take the form of a military uniform or poncho printed with an adaptive adversarial camouflage pattern. The system could optimize a pattern for a sniper's coat that confuses both visual and IR scopes on enemy drones. The soldier's gear might even have an e-ink layer allowing it to update patterns based on environment (woodland vs. desert) during a mission.

Another example is vehicle and aircraft camouflage. This may be a multi-spectral adversarial coating on vehicles or aircraft. For instance, a naval ship could be painted with a pattern that not only visually blends with ocean waves at a distance but also includes radar-absorbing sections and thermal management to mask engine heat. The invention's engine would tailor the pattern to the ship's shape and the likely sensor angles from satellites or submarines.

Yet another example is static installation concealment. This may include deploying camouflage nets or panels on buildings, antenna towers, or other infrastructure, with adversarial patterns tuned to local backgrounds and sensor threats. The system can account for slight movements (like a net moving in wind) in simulation to ensure the pattern remains effective. It could also camouflage sensors themselves (to hide security cameras from being spotted by AI analysis of surveillance footage).

Another field device may be an adversarial decoy deployables. These may be inflatable or unmanned decoys that simulate real assets. For example, an inflatable tank decoy equipped with printed adversarial patterns plus a heat source and corner reflectors placed as per the system's design can appear real to an AI observer. The integrator would output the print layout for the inflatable's skin, and a signal script for the heat source.

There may be a system of devices working in a synchronized manner. For example, a drone swarm illusions may use multiple drones or UAVs to collectively create a deceptive signature. The system can optimize patterns or emissions across a group of drones such that, from the enemy's sensor perspective, it looks like a single larger object or a formation of objects. For instance, a swarm of small drones could coordinate IR LED projections to make a thermal camera “see” a moving human figure on the ground where there is none. The integrator would assign each drone a piece of the overall pattern or signal to emit, accounting for their positions.

These examples demonstrate how the core adversarial optimization and integration technology can be applied in practice. Across these scenarios, common themes may include multi-modal effectiveness (patterns are effective against various sensor types concurrently), adaptive realism (patterns remain plausible in the real world), and deployment practicality (the system handles the gritty details of turning designs into field-ready solutions). The described embodiments and use cases show that the disclosed configurations beneficially enhance stealth and deception capabilities against AI-based detection, while remaining mindful of real-world deployment constraints and requirements.

In sum, the multi-modal adversarial optimization engine and deployment integrator provides a powerful and flexible framework for dynamically controlling the detectability of objects. By uniting sophisticated AI-driven pattern generation with a full-stack deployment pipeline, it enables a new class of counter-surveillance and counter-targeting measures that are effective, adaptive, and deployable at scale.

### Computing Machine Architecture

Turning now to FIG. 5, illustrated is an e5ample machine to read and e5ecute computer readable instructions, in accordance with an embodiment. Specifically, FIG. 5 shows a diagrammatic representation of the data processing service (and/or data processing system) in the e5ample form of a computer system 500. The computer system 500 is structured and configured to operate through one or more other systems (or subsystems) as described herein. The computer system 500 can be used to execute instructions 524 (e.g., program code or software) for causing the machine (or some or all of the components thereof) to perform any one or more of the methodologies (or processes) described herein. In e5ecuting the instructions, the computer system 500 operates in a specific manner as per the functionality described. The computer system 500 may operate as a standalone device or a connected (e.g., networked) device that connects to other machines. In a networked deployment, the machine may operate in the capacity of a server machine or a client machine in a server-client network environment, or as a peer machine in a peer-to-peer (or distributed) network environment.

The computer system 500 may be a server computer, a client computer, a personal computer (PC), a tablet PC, a smartphone, an internet of things (IoT) appliance, a network router, switch or bridge, or other machine capable of e5ecuting instructions 524 (sequential or otherwise) that enable actions as set forth by the instructions 524. Further, while only a single machine is illustrated, the term “machine” shall also be taken to include any collection of machines that individually or jointly e5ecute instructions 524 to perform any one or more of the methodologies discussed herein.

The example computer system 500 includes a processor system 502. The processor system 502 includes one or more processors. The processor system 502 may include, for example, a central processing unit (CPU), a graphics processing unit (GPU), neural processing unit (NPU), a tensor processing unit (TPU), a digital signal processor (DSP), a controller, a state machine, one or more application specific integrated circuits (ASICs), one or more radio-frequency integrated circuits (RFICs), or any combination of these. The processor system 502 e5ecutes an operating system for the computing system 500. The computer system 500 also includes a memory system 504. The memory system 504 may include or more memories (e.g., dynamic random-access memory (RAM), static RAM, cache memory). The computer system 500 may include a storage system 516 that includes one or more machine readable storage devices (e.g., magnetic disk drive, optical disk drive, solid state memory disk drive).

The storage unit 516 stores instructions 524 (e.g., software) embodying any one or more of the methodologies or functions described herein. For example, the instructions 524 may include instructions to perform the functional operation of the processes described with FIGS. 1A through 4. The instructions 524 may also reside, completely or at least partially, within the memory system 504 or within the processing system 502 (e.g., within a processor cache memory) during execution thereof by the computer system 500, the main memory 504 and the processor system 502 also constituting machine-readable media. The instructions 524 may be transmitted or received over a network 526, such as the network 526, via the network interface device 520. By way of example, the modules of the processing pipeline in FIG. 1 may be structured so that the processing system 502 is specialized for performing the functionality described therein. Each module may structure the processing system to be specific for that functionality when executed.

The storage system 516 should be taken to include a single medium or multiple media (e.g., a centralized or distributed database, or associated caches and servers communicatively coupled through the network interface system 520) able to store the instructions 524. The term “machine-readable medium” shall also be taken to include any medium that is capable of storing instructions 524 for e5ecution by the machine and that cause the machine to perform any one or more of the methodologies disclosed herein. The term “machine-readable medium” includes, but not be limited to, data repositories in the form of solid-state memories, optical media, and magnetic media.

In addition, the computer system 500 can include a display system 510. The display system 510 may drive firmware (or code) to enable rendering on one or more visual devices, e.g., drive a plasma display panel (PDP), a liquid crystal display (LCD), or a projector. The computer system 500 also may include one or more input/output systems 512. The input/output (IO) systems 512 may include input devices (e.g., a keyboard, mouse (or trackpad), a pen (or stylus), microphone) or output devices (e.g., a speaker). The computer system 500 also may include a network interface system 520. The network interface system 520 may include one or more network devices that are configured to communicate with an e5ternal network 526. The e5ternal network 526 may be a wired (e.g., ethernet) or wireless (e.g., Wi-Fi, BLUETOOTH, near field communication (NFC).

The processor system 502, the memory system 504, the storage system 516, the display system 510, the IO systems 512, and the network interface system 520 are communicatively coupled via a computing bus 508.

### Additional Configuration Considerations

Disclosed includes a system to influence the detectability of a target object by machine perception across multiple sensor modalities. The system receives input data including a representation of the target object and an objective corresponding to either reducing detectability or inducing a designated detection (decoy) for that object. A plurality of candidate adversarial patterns is generated for the target object, and each candidate pattern is evaluated in a simulated environment across the plurality of sensor modalities using an ensemble of detector models, including models that fuse multi-modal sensor data. An iterative optimization loop, which may employ techniques such as reinforcement learning, adjusts the candidate patterns based on detection performance feedback until an optimized adversarial pattern meets a predetermined performance threshold for the specified stealth or decoy objective. The finalized adversarial pattern is then compiled for deployment, with output instructions prepared for the chosen medium. Deployment can be physical (e.g. printing or projecting a pattern on the object) or digital (e.g., applying an overlay in sensor feeds), and deployed systems may return feedback that the platform uses (e.g., via federated learning) to continuously improve the adversarial pattern generation model over time.

Also disclosed are multi-modal fusion detectors. In addition to modality-specific detection models, the detector ensemble may include one or more multi-modal fusion detector models that process combined sensor inputs. For example, a fusion detector neural network could take both visual spectrum imagery and thermal infrared data as joint inputs and output a single detection confidence across those modalities. By incorporating such multi-modal detectors, the system simulates advanced adversary perception systems that integrate multiple sensor streams for target recognition. This ensures that the adversarial optimization accounts for sensor fusion scenarios, the adversarial pattern is evaluated and tuned against detectors that examine cross-modal signatures, preventing a situation where the pattern only confounds individual sensors but fails when confronted with a fused multi-sensor analysis. The presence of multi-modal fusion detectors in the ensemble thus enhances the robustness of the optimized pattern across complex detection systems.

Further disclosed is digital deployment of adversarial patterns. In addition to producing physical adversarial patterns (e.g. printed camouflage or emitted signals), the system also supports digital adversarial patterns for deployment of adversarial effects. In one example, the output compiler can generate a digital overlay or filter that may be applied to real-time sensor data or video feeds. Rather than modifying the physical object, the adversarial pattern in this case is injected downstream in the electronic domain, for example, by superimposing a perturbation pattern onto a surveillance camera video stream or by algorithmically altering image data from a sensor. This digital adversarial overlay is designed such that when the altered feed is processed by an AI detector, the target object is either hidden or triggers a false classification, depending on the objective of the system. The deployment integrator can provide software instructions or plug-in modules to integrate this adversarial filter into existing imaging systems. Such digital deployment offers a stealthy, rapid means to introduce adversarial patterns in scenarios where one may not have physical access to the object or where altering the data stream is more practical than altering the object itself. The system ability to output adversarial patterns in a digital format (e.g., as image transformation code or augmented reality overlays) extends the protective and deceptive capabilities to purely electronic battlegrounds, complementing the physical-world camouflage and decoy implementations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of components, modules, or mechanisms. Modules may constitute either software modules (e.g., code embodied on a machine-readable medium and processor executable) or hardware modules. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module is a tangible component that may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

Upon reading this disclosure, those of skill in the art will appreciate still additional alternative structural and functional designs for a system and a process for a multi-modal adversarial optimization engine and deployment integrator through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A non-transitory computer readable storage medium comprising stored instructions that when executed by a processor system cause the processor system to:
receive input data including a representation of the target object and an objective corresponding to reduce detectability or induce a designated detection of the target object;
generate a plurality of candidate adversarial patterns based on the objective for the target object;
simulate, for each candidate adversarial pattern of the plurality of adversarial patterns, an integration of the target object in a virtual environment across a plurality of sensor modalities;
evaluate each simulated candidate adversarial pattern using an ensemble of machine-learned detector models corresponding to the plurality of sensor modalities, the detector models producing detection outputs corresponding to the target object;
calculate a performance metric for each simulated candidate adversarial pattern based on the detection outputs, the performance metric corresponding to the objective;
determine whether the performance metric reaches a predetermined threshold level for the objective; and
execute one of instructions to:
select the simulated adversarial pattern as an optimized adversarial pattern in response to reaching the performance metric, or
iteratively adjust, in response to not reaching the predetermined threshold level performance metric, the simulated candidate adversarial pattern until it converges on meeting the predetermined threshold level metric for an optimized output adversarial pattern for the target object; and
compile the optimized adversarial pattern into an output file for the target object.

2. The non-transitory computer readable storage medium of claim 1, wherein the instructions to simulate the integrated target object further comprises instructions to create a digital twin model of the target object and rendering the target object with each candidate adversarial pattern under representative environmental conditions for each of the sensor modalities.

3. The non-transitory computer readable storage medium of claim 2, wherein the sensor modalities include at least one of sensors selected from visual spectrum imaging, infrared imaging, LiDAR ranging, and radar sensing.

4. The non-transitory computer readable storage medium of claim 1, wherein the instructions to compile the optimized adversarial pattern into deployment instructions further comprises instructions to create deployment instructions specific to a selected deployment medium, the deployment instructions including data for reproducing the optimized adversarial pattern on the target object.

5. The non-transitory computer readable storage medium of claim 4, wherein the instructions to compile the optimized adversarial pattern into deployment instructions further comprises instructions to:
generate a deployment bundle, the deployment bundle comprising one or more image files or device control files encoding the pattern, a tiling schema dividing the optimized adversarial pattern into segments for application on the target object, and alignment markers or calibration data for assembling or projecting the pattern accurately on the target object.

6. The non-transitory computer readable storage medium of claim 1, further comprising instructions to:
capture sensor feedback data from the target object after deploying the optimized adversarial pattern using one or more sensors corresponding to the sensor modalities; and
analyze the sensor feedback data with the ensemble of detector models to verify that the optimized adversarial pattern achieves the optimization objectives.

7. The non-transitory computer readable storage medium of claim 1, further comprising instructions to:
iteratively modify the candidate adversarial pattern in response to feedback based on the performance metric and a current candidate adversarial pattern;
select a modification action for the current adversarial candidate pattern from a predefined set of perturbation operations; and
receive a reward based on a reduction in the detectability of the target object.

8. The non-transitory computer readable storage medium of claim 6, further comprising instructions to output the optimized adversarial pattern for application of use with the deployment instructions to the selected deployment medium at least one of physically or electronically.

9. A computer-implemented method for modulating detectability of a target object by machine perception, comprising:
receiving input data including a representation of the target object and an objective corresponding to reduce detectability or induce a designated detection of the target object;
generating, using an adversarial pattern generator, a plurality of candidate adversarial patterns based on the objective for the target object;
simulating, for each candidate adversarial pattern of the plurality of adversarial patterns, an integration of the target object in a virtual environment across a plurality of sensor modalities;
evaluating each simulated candidate adversarial pattern using an ensemble of machine-learned detector models corresponding to the plurality of sensor modalities, the detector models producing detection outputs corresponding to the target object;
calculating a performance metric for each simulated candidate adversarial pattern based on the detection outputs, the performance metric corresponding to the objective;
determining whether the performance metric reaches a predetermined threshold level for the objective; and
performing one of:
selecting the simulated adversarial pattern as an optimized adversarial pattern in response to reaching the performance metric, or
iteratively adjusting, in response to not reaching the predetermined threshold level performance metric, the simulated candidate adversarial pattern until it converges on meeting the predetermined threshold level metric for an optimized output adversarial pattern for the target object; and
compiling the optimized adversarial pattern into an output file for the target object.

10. The method of claim 9, wherein simulating the integrated target object comprises creating a digital twin model of the target object and rendering the target object with each candidate adversarial pattern under representative environmental conditions for each of the sensor modalities.

11. The method of claim 10, wherein the sensor modalities include at least one of sensors selected from visual spectrum imaging, infrared imaging, LiDAR ranging, and radar sensing.

12. The method of claim 9, wherein compiling the optimized adversarial pattern into deployment instructions further comprises creating deployment instructions specific to a selected deployment medium, the deployment instructions including data for reproducing the optimized adversarial pattern on the target object.

13. The method of claim 12, wherein compiling the optimized adversarial pattern into deployment instructions further comprises:
generating a deployment bundle, the deployment bundle comprising one or more image files or device control files encoding the pattern, a tiling schema dividing the pattern into segments for application on the target object, and alignment markers or calibration data for assembling or projecting the pattern accurately on the target object.

14. The method of claim 9, further comprising:
capturing sensor feedback data from the target object after deploying the optimized adversarial pattern using one or more sensors corresponding to the sensor modalities; and
analyzing the sensor feedback data with the ensemble of detector models to verify that the deployed adversarial pattern achieves the optimization objectives

15. The method of claim 14, further comprising outputting the optimized adversarial pattern for application of use with the deployment instructions to the selected deployment medium at least one of physically or electronically.

16. The method of claim 9, wherein the objective corresponds to a decoy mode in which the adversarial pattern is optimized to increase detectability of the target object or to induce a designated false target detection by the machine-learned detector models.

17. A system to influence detectability of a target object, the system comprising:
an input processing module configured to receive data of a target object and context parameters corresponding to detectability of the target object;
a pattern generator module configured to generate a plurality of candidate adversarial patterns for the target object;
a multi-modal simulation module configured to:
simulate the target object with each candidate adversarial pattern of the plurality of candidate adversarial patterns, the simulation in a virtual environment across a plurality of sensor modalities, and,
produce simulated sensor outputs for each sensor modality of the plurality of sensor modalities;
a detector ensemble module comprising a plurality of trained detector models each corresponding to a sensor modality of the plurality of sensor modalities, the detector ensemble module configured to process the simulated sensor outputs to produce detection metrics indicative of whether the target object would be detected or misclassified under each candidate adversarial pattern of the plurality of candidate adversarial patterns;
an optimization module configured to iteratively adjust the candidate adversarial patterns until a threshold is reached at which point an optimized adversarial pattern is generated; and
an output compiler module configured to generate output data for the optimized adversarial pattern.

18. The system of claim 15, further comprising an integrator module configured to interface with at least one output device, the integrator module further configured to transmit instruction for deployment of the optimized adversarial pattern on the target object or in an environment

19. The system of claim 16, wherein the integrator module further comprising a verification module arranged to receive deployment data from one or more verification sensors of the target object after deployment of the optimized adversarial pattern on the target object, the received deployment data for analyzing performance of the optimized adversarial pattern.

20. The system of claim 15, wherein the pattern generator module further comprises a neural network-based generative model that has been trained adversarially against data from the detector ensemble module to produce patterns that reduce detectability, the optimization module further configured to adjust parameters of the generative model based on feedback from the detector ensemble module.

21. The system of claim 15, wherein the output compiler module is configured to produce a pattern deployment bundle comprising a plurality of tiled image segments of the optimized adversarial pattern for printing or fabrication, corresponding device control files for electronic display or emission devices, and registration mark data for aligning the pattern segments on the target object.

22. The system of claim 15, wherein the integrator module further comprises:
an environment adjustment component that generates data corresponding to the optimized adversarial pattern to compensate for a non-planar geometry of a surface of the target object, and
a calibration component that inserts visual or electronic fiducials to guide proper positioning of the pattern during deployment.

23. The system of claim 17, wherein the optimization module further comprises a reinforcement learning agent configured to iteratively modify the candidate adversarial patterns based on a reward signal derived from the detection metrics of the detector ensemble module.

24. The system of claim 17, further comprising a network interface to collect detection performance data from a plurality of deployed target objects, and wherein the pattern generator module updates its parameters using a federated learning process that aggregates the collected performance data from the plurality of deployed target objects.

25. The system of claim 17, wherein the detector ensemble module comprises at least one multi-modal fusion detector model configured to process combined inputs from multiple sensor modalities of the plurality of sensor modalities to produce a detection output.

26. The system of claim 20, wherein the generative model comprises at least one of: a generative adversarial network (GAN), a variational autoencoder (VAE), a diffusion model, or a transformer-based generative model.

27. The system of claim 18, wherein the at least one output device comprises at least one of a two dimensional printing apparatus configured to produce the adversarial pattern on a physical substrate and a three-dimensional printing apparatus configured to produce the adversarial pattern as a physical object.

28. The system of claim 18, wherein the at least one output device comprises at least one of a projection device configured to project the adversarial pattern onto the target object and an electronic display configured to display or superimpose the adversarial pattern.

29. The system of claim 18, wherein the at least one output device comprises at least one of an electromagnetic signal emitter configured to emit the adversarial pattern as a signal in a radar or radio frequency spectrum and and an acoustic emitter configured to output the adversarial pattern as an audio signal.
